(19) United States
(12) Patent Application Publication
(10) Pub. No.: US 2011/0261394 A1
(43) Pub. Date: Oct. 27, 2011

(54) PRINTER STAND

(76) Inventor: Atsushi TANAKA, Musashimurayama-shi (JP)

(21) Appl. No.: 13/006,720

(22) Filed: Jan. 14, 2011

(30) Foreign Application Priority Data
Apr. 26, 2010 (JP) 2010-101176

(51) Int. Cl. G06F 3/12; H05K 7/00

(52) U.S. Cl. 358/1.15; 248/346.03

(57) ABSTRACT

A printer stand includes a main body into which a base part and a support part are integrally formed, the base part being in contact with a surface on which the printer stand is set up, the support part being that to which a printer is detachably attached with its setup posture changed and a display part for displaying information.

### PRIORITY CLAIM

The present application is based on and claims priority from Japanese Patent Application No. 2010-101176, filed on, Apr. 26, 2010, the disclosure of which is hereby incorporated by reference in its entirety.

### BACKGROUND OF THE INVENTION

1. Field of the Invention

The present invention relates to a printer stand.

2. Description of the Related Art

A printer with a case shaped almost like a cuboid can be set up either in a horizontal posture (which makes the overall height lower) or in a vertical posture (which makes the overall height higher), as long as its discharge port from which to discharge a printed medium such as a printed sheet is not blocked.

In particular, in printers which are often used for various Point of Sale (POS) systems, including retail POS systems, food service POS systems, gas-station POS systems and banking POS systems, users arbitrarily change the postures in which the printers are set up depending on restriction on their setup spaces and the like in many cases.

In this respect, if a printer originally expected to be set up in the horizontal posture is set up in the vertical posture, the stability of the setup may deteriorate not a little.

Against this background, for securing the stability of its set up even in a case where a printer is set up with its posture changed, there has been proposed a printer stand configured to be attached to the printer whose posture is changed (Japanese Utility Model Registration Application Publication No. Hei 02-142050 and Japanese Patent Application Publication No. 2005-288749).

When a printer is set up in a horizontal posture with the above-mentioned printer stand being attached to the printer, the printer is often placed in a way that: the top surface (such as a surface from which mediums such as sheets are discharged) of the printer set up in the horizontal posture faces to users; and the undersurface of the printer set up in the horizontal posture faces to a wall surface or the like.

On the other hand, relatively small retail shops and the like may use an account processing system configured by a personal computer, a cash drawer (a device in which to keep cash), a display unit and a printer, instead of an all-in-one type of cash register in some cases.

Furthermore, such retail shops and the like may use the printer which is used to do things such as issuing receipts in the following state because space of a place for accounting is restricted. Specifically, the printer is set up not only in the vertical posture, but also in a way that the side which would be the undersurface of the printer if the printer is set up in the horizontal posture is faced toward customers.

### SUMMARY

The present invention has been made with the above-described situation taken into consideration. An object of the present invention is to provide a printer stand capable of enhancing the use value.

In order to achieve the above object, an embodiment of the present invention provides a printer stand including a main body into which a base part and a support part are integrally formed, the base part being in contact with a surface on which the printer stand is set up, the support part being that to which a printer is detachably attached with its setup posture changed and a display part for displaying information.

### BRIEF DESCRIPTION OF DRAWINGS

FIG. 1 is a perspective view of an example of a printer which is attached to a printer stand according to an embodiment of the present invention (while the printer is used alone (in a horizontal posture)).

FIG. 2 is a perspective view showing a condition of the printer shown in FIG. 1, which is put in a vertical posture.

FIG. 3 is a perspective view showing a condition of the printer shown in FIG. 2, which is viewed from its back side (from the side which would be the undersurface of the printer if the printer is put in the horizontal posture).

FIG. 4 is a perspective view showing the printer stand according to the embodiment of the present invention, to which the printer shown in FIG. 1 is attached in the vertical posture.

FIG. 5 is a perspective view showing a condition of the printer stand shown in FIG. 4, which is viewed from its back side (from the undersurface side of the printer if the printer is put in the horizontal posture).

FIG. 6 is a perspective view showing a condition in which the illustrated printer is attached to the printer stand shown in FIG. 4 in the vertical posture (in the posture shown in FIG. 2).

FIG. 7 is a perspective view showing a condition of the printer stand to which the printer is attached as shown in FIG. 6, which is viewed from its back side (from the undersurface side of the printer put in the horizontal posture, or from a display part side).

FIG. 8 is a perspective view showing a condition in which a main body and the display part are separated from each other.

FIG. 9 is a perspective view of the display part, which is viewed from its back side (from a surface which faces a back plate of a support part).

FIG. 10 is a diagram showing how the display part as a separate body is engaged with the main body.

FIG. 11 is a diagram (Part 1) showing a stand-alone simple account processing system including a thermal printer and the display part of the printer stand, which is an alternative to an all-in-one type of cash register.

FIG. 12 is a diagram (Part 1) showing a network-connected simple account processing system including the thermal printer and the display part of the printer stand, which is an alternative to the all-in-one type of cash register.

FIG. 13 is a diagram (Part 2) showing the stand-alone simple account processing system including the thermal printer and the display part of the printer stand, which is the alternative to the all-in-one type of cash register.

FIG. 14 is a diagram (Part 2) showing the network-connected simple account processing system including the thermal printer and the display part of the printer stand, which is the alternative to the all-in-one type of cash register.

### DESCRIPTION OF THE PREFERRED EMBODIMENT

Hereinbelow, referring to the drawings, descriptions will be provided for a concrete embodiment of a printer stand according to the present invention.

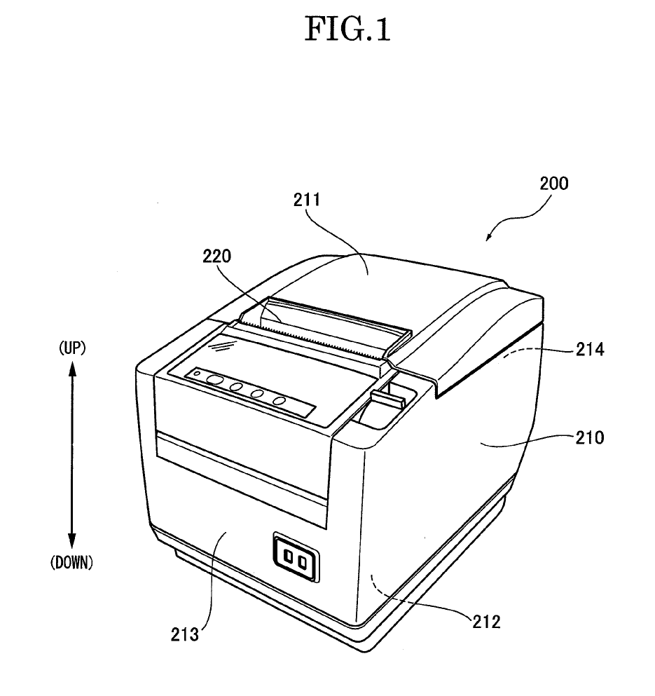

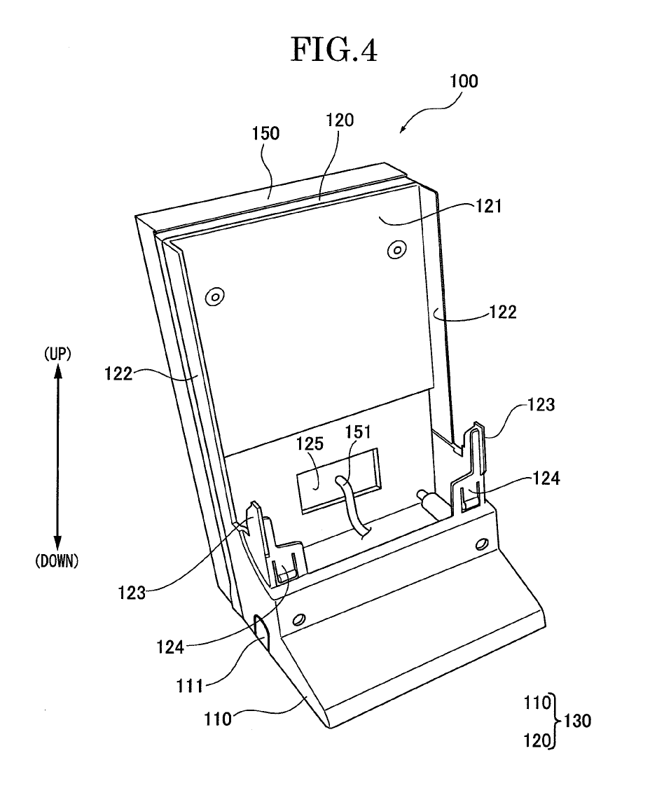

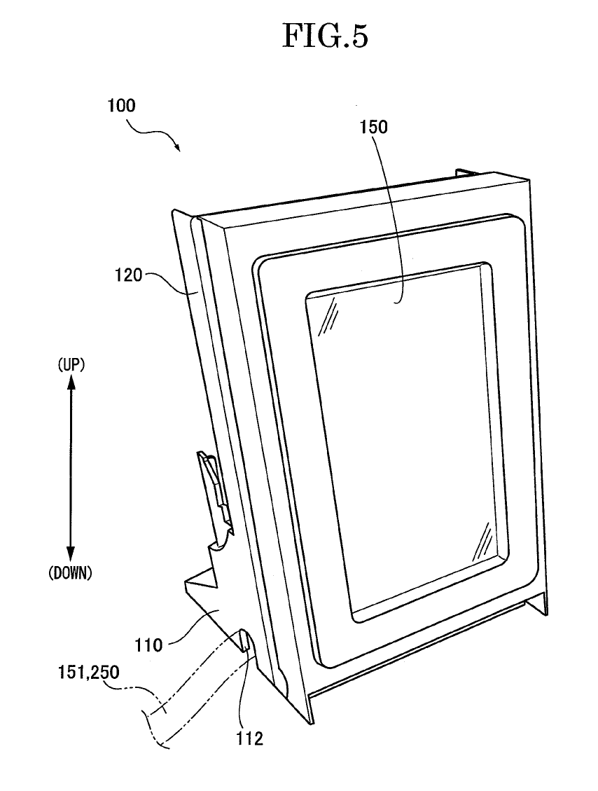

FIGS. 1, 2 and 3 are diagrams showing a small-sized thermal printer 200 (printer) used mainly for a POS system, which is attached to a printer stand 100 according to an embodiment of the present invention. FIGS. 4 and 5 are diagrams showing the printer stand 100.

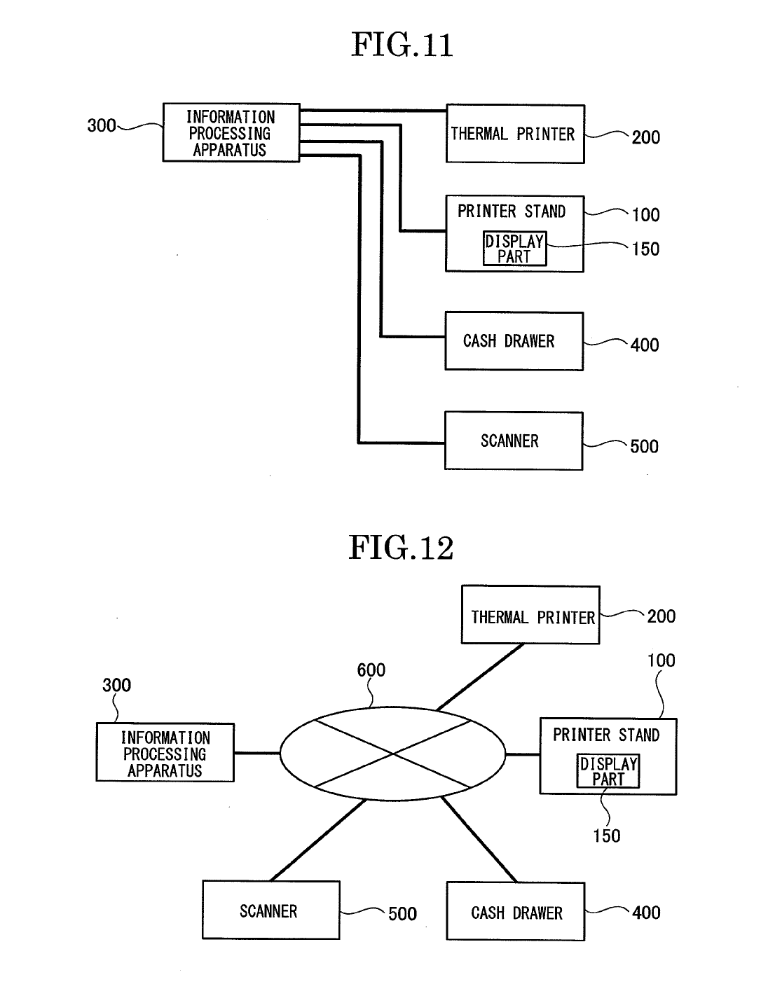

As shown in FIG. 11, for example, the illustrated thermal printer 200 is directly connected to an information processing apparatus 300 such as a personal computer or a server, or is connected to the information processing apparatus 300 through a network 600 as shown in FIG. 12. The thermal printer 200 is an apparatus for outputting printing information by printing on a sheet (medium), the outputting of the printing information being instructed by the information processing apparatus 300. A case 210 of the thermal printer 200 is shaped almost like a cuboid. When used alone, the thermal printer 200 is set up in what is termed as a “horizontal posture,” which makes the printer's overall height lower, as shown in FIG. 1.

In addition, a sheet discharge port 220 for discharging sheets on which various pieces of information are printed by a thermal head of this thermal printer 200 is formed in a top surface (an upward-facing surface) 211 of the thermal printer 200 as set up in the horizontal posture shown in FIG. 1.

Furthermore, a surface opposite from this top surface 211 is an undersurface 212 which serves as a placement surface for the horizontal posture. In the illustration, a surface on the front side is a front surface 213, and a surface (not illustrated) opposite from this front surface 213 is a back surface 214.

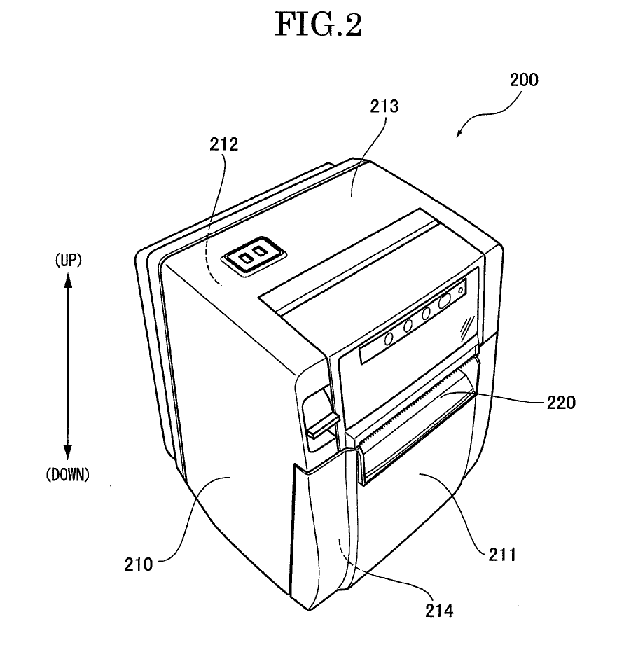

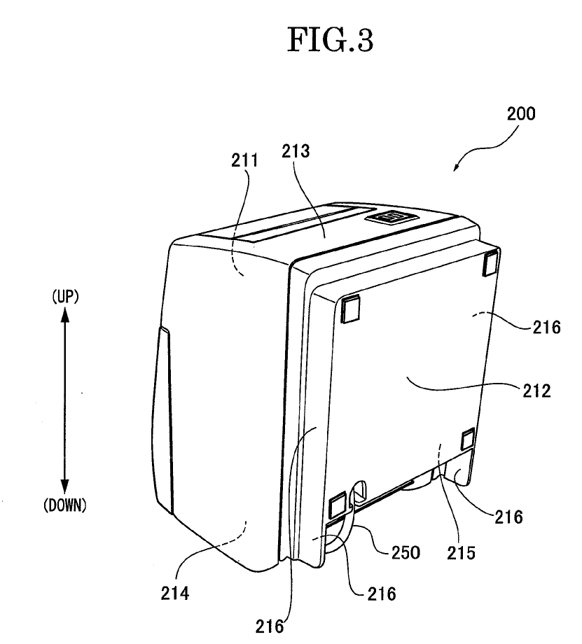

As shown in FIGS. 2 and 3, this thermal printer 200 can also be set up in a vertical posture with the back surface 214 faced down, and with the front surface 213 faced up, instead of in the above-mentioned horizontal posture.

The center of gravity of this thermal printer 200 is higher when the thermal printer 200 is set up in this vertical posture than in the horizontal posture. For this reason, its setup stability is lower in the vertical posture than in the horizontal posture.

With this taken into consideration, the printer stand 100 for holding the thermal printer 200 in the vertical posture which is different from the setup posture (horizontal posture) expected for the thermal printer 200 set up alone is used for stably setting up the thermal printer 200 in the vertical posture.

As shown in FIGS. 4 and 5, this printer stand 100 includes: a base part 110 spreading horizontally and in contact with a surface on which the printer stand 100 is set up; a support part 120 extending vertically upward from the base part 110, and detachably supporting the thermal printer 200 in the vertical posture; and a thin display part 150 provided on the back surface side of the support part 120, and formed from a liquid crystal or the like.

Note that the base part 110 and the support part 120 are integrally formed into a main body 130.

The base part 110 is a part which is in direct contact with the top surface of a table or counter on which this printer stand 100 is set up. Holes 111, 112 are formed in the respective two side surfaces of this base part 110. The holes 111, 112 are those through which a connection cable 250 and like, such as a power supply cable and a data communication cable, which extend from the back surface 214 of the attached thermal printer 200 toward the inside of the base part 110 are drawn out of the base part 110.

These holes 111, 112 are covered with the respective covers before used. When a cover is removed from one of the side surfaces of the base part 110 through which the connection cable 250 and the like are drawn out, a corresponding one of the holes 111, 112 is formed.

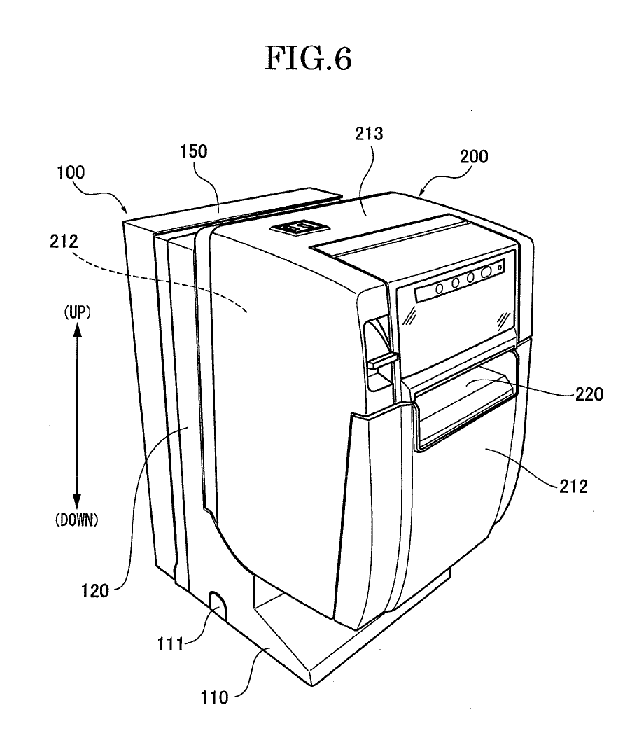

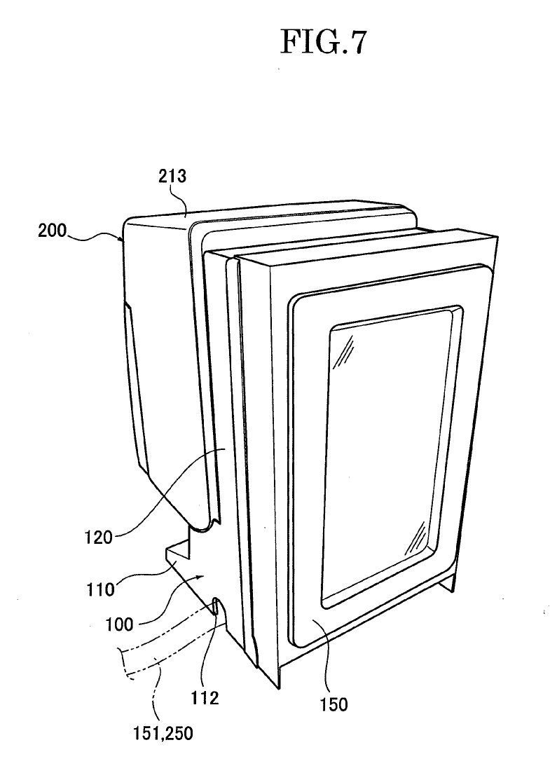

In the illustrated case, the hole 111 on the side shown in FIG. 6 remains to be covered with its cover. The cover is removed from the hole 112 on the side shown in FIG. 7, and the connection cable 250 of the thermal printer 200 attached to this printer stand 100 and a connection cable 151 of the display part 150, which will be described later, are drawn out through the hole 112 (although the illustration is omitted).

Note that the connection cable 151 and the like may be drawn out toward the front of the display part 150 through a space formed under the display part 150 shown in FIG. 5, 7 and so forth.

As shown in FIG. 4, the support part 120 includes: a back plate 121 extending vertically upward from the rear end of the base part 110; side plates 122, 122 formed along the respective two side edges of this back plate 121; two upward-projecting protrusions 123, 123 to be inserted in a hollow part 215 (refer to FIG. 3) formed along the undersurface 212 in a lower portion of the thermal printer 200, which is near the back surface 214; and tongue-shaped elastic lock parts 124, 124 close to the respective protrusions 123, 123.

The back plate 121 of the support part 120 faces the undersurface 212 of the attached thermal printer 200. The two side plates 122, 122 are in contact with the respective two sidewall lower parts 216, 216 of the thermal printer 200 from the outside so as to sandwich the thermal printer 200 in the horizontal direction.

In addition, an opening 125 through which the connection cable 151, such as the power supply cable and data communication cable of the display part 150, is made to pass is formed in this back plate 121.

The protrusions 123, 123 inserted in the hollow part 215 of the thermal printer 200 are in contact with the respective two sidewall lower parts 216, 216 of the thermal printer 200 from the inside. The thermal printer 200 supported by these protrusions 123, 123, the side plates 122, 122 and the back plate 121 is prevented from falling down in the frontward and backward directions and in the sideways directions. Accordingly, the thermal printer 200 is held in the vertical posture.

While the thermal printer 200 is attached to the printer stand 100 in the vertical posture, the elastic lock parts 124, 124 engage with the outer edge of the case 210 of the thermal printer 200, and thus prevent the thermal printer 200 from easily coming off the printer stand 100.

The thermal printer 200 is detached from the printer stand 100 as follows. While the thermal printer 200 is being attached to the printer stand 100 (refer to FIG. 6), once a lower portion of the top surface 211 (corresponding to the front surface in the illustrated vertical posture) of the thermal printer 200 is pressed toward the back plate 121, and the elastic lock parts 124, 124 disengage from the outer edge of the case 210 of the thermal printer 200. Subsequently, once the thermal printer 200 is pulled upward with the elastic lock parts 124, 124 kept disengaging therefrom, the two protrusions 123, 123 of the printer stand 100 come out of the hollow part 215 of the thermal printer 200.

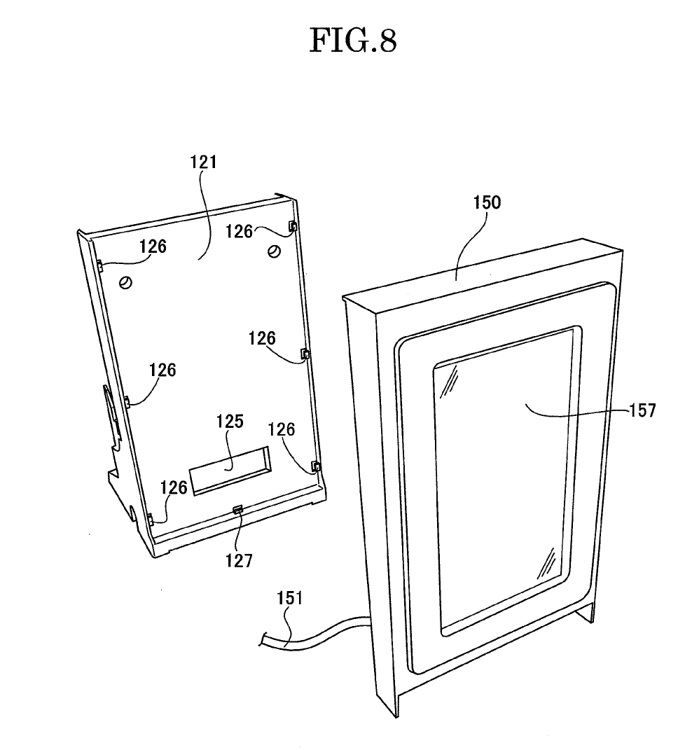

The display part 150 is provided on the back surface of the back plate 121 of the printer stand 100 (on a surface (rear surface) opposite from the surface on which the thermal printer 200 is attached). In the printer stand 100 of this embodiment, as shown in FIG. 8, this display part 150 can be attached and detached to and from the back plate 121.

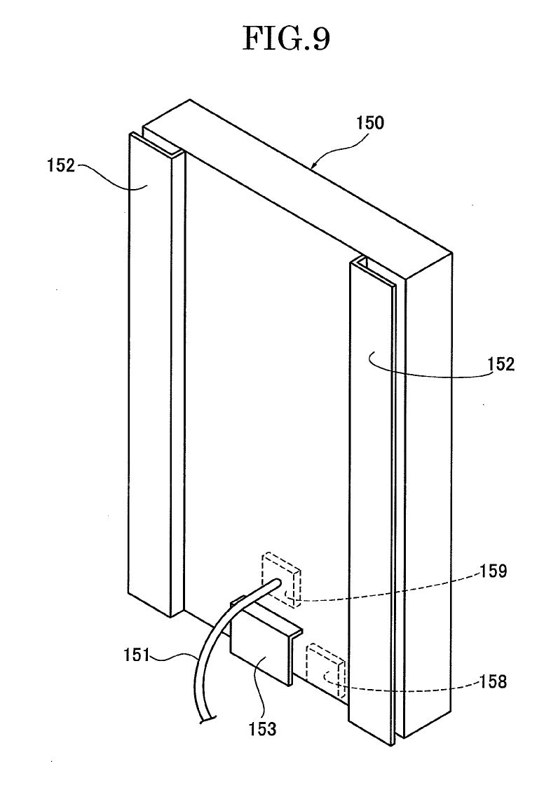

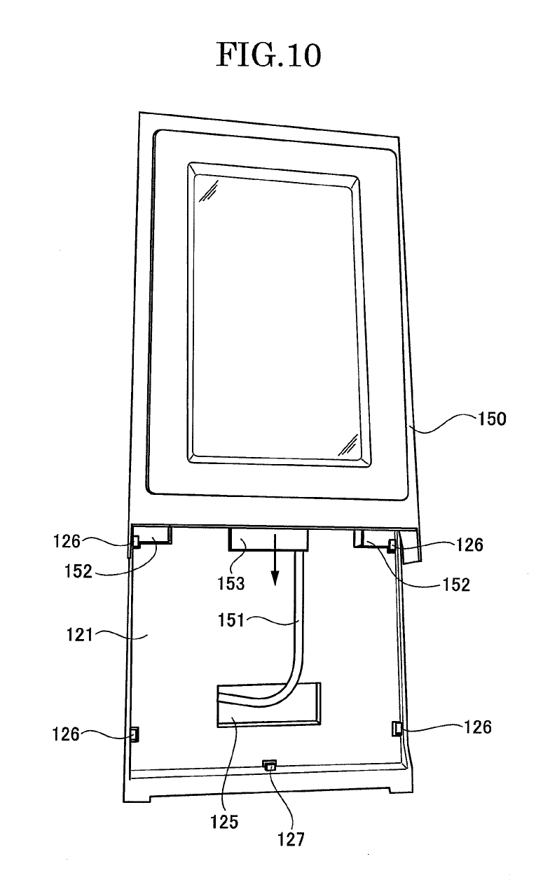

To put it specifically, as shown in FIG. 8, the back surface of the back plate 121 of the printer stand 100 is provided with a total of 6 claws 126 (engagement parts of the main body) in its two side edge portions, and one claw 127 (an engagement part of the main body) in its lower edge portion. As shown in FIG. 9, vertically-extending flanges 152, 152 (engagement parts of the display part) capable of engaging with and disengaging from the claws 126 of the back plate 121 are formed in the respective two side portions of the back surface (a surface opposed to the back plate 121) of the display part 150. A flange 153 (an engagement part of the display part) capable of engaging with and disengaging from the claw 127 of the back plate 121 is provided in a lower end portion of the back surface.

The two flanges 152, 152 of the display part 150 are inserted in the space surrounded by the upper paired left and light claws 126, 126 of this back plate 121 and the main body of the back plate 121 from under the flanges 152, 152. Subsequently, the display part 150 is made to descend without removing the display part 150. Thereby, the two flanges 152, 152 are disposed in the space surrounded by all the claws 126 and the main body of the back plate 121, and the claws 126 and the flanges 152 engage with each other. The flange 153 is disposed in the space between the claw 127 and the main body of the back plate 121, and the claw 127 and the flange 153 engage with each other. Accordingly, the display part 150 is coupled to the back plate 121, and the integrated printer stand 100 is built up.

The separation of the display part 150 and the main body from each other by detaching the display part 150 from the back plate 121 can be achieved by an operation whose sequence is reverse from the operation for attaching the display part 150 to the back plate 121, that is to say, by releasing the engagement between the claw 127 and the flange 153 as well as the engagement between the claws 126 and the flanges 152,152 by pulling the display part 150 upward along the back plate 121.

In this respect, as shown in FIG. 9, the display part 150 of the printer stand 100 includes a medium slot 158 (a medium connecting part) to which a storage medium is connected. Information intended to be displayed on this display part 150 is stored in the storage medium. As characters and images, various pieces of information stored in the storage medium, such as a flash memory, which is connected to the medium slot 158 are displayed on the display part 150.

In addition, this display part 150 may include an input part 159 (refer to FIG. 9) to which an external information processing apparatus 300 for outputting information intended to be displayed on the display part 150 is connected, instead of the medium slot 158. It is a matter of course that the display part 150 may include both the medium slot 158 and the input part 159.

Note that the information processing apparatus 300 and the input part 159 of the display part 150 may be connected together directly as shown in FIG. 11, or through the network 600 as shown in FIG. 12 (it does not matter whether the connection may be wired or wireless). Either connection mode makes it possible to display information displaying of which is instructed by the information processing apparatus 300.

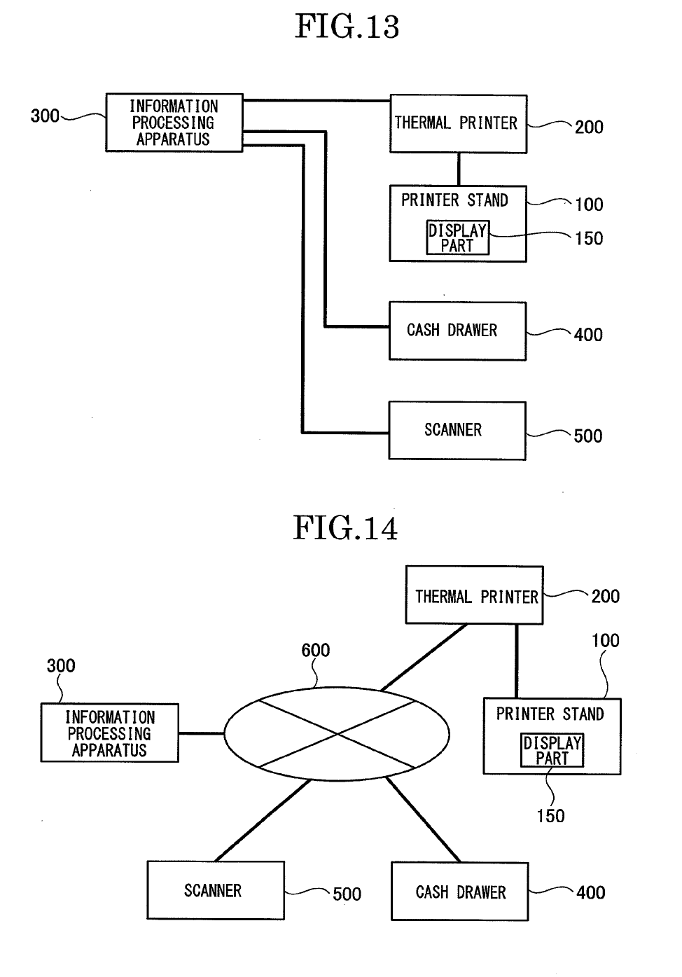

In this respect, the connection modes shown in FIGS. 11 and 12 represent the connection of the display part 150 of the printer stand 100 to the information processing apparatus 300 directly and through the network 600, respectively. For example, as shown in FIG. 13, the display part 150 may be connected to the information processing apparatus 300 through the thermal printer 200 held by the printer stand 100, or may be connected, as shown in FIG. 14, to the information processing apparatus 300 through the thermal printer 200 connected to the network 600.

The connection mode in which, as described above, the display part 150 is connected to the information processing apparatus 300 through the thermal printer 200 exerts the same operation and effect as the connection modes shown in FIGS. 11 and 12 do. In addition, the connection destination of the display part 150 is the thermal printer 200 which is disposed extremely close to the display part 150 as a result of being attached to the printer stand 100. For these reasons, the length of the connection cable 151 for connecting the display part 150 and this thermal printer 200 together can be made extremely short. The length of the connection cable 151 can be made shorter than in the system (refer to FIG. 11) in which the connection destination of the display part 150 is the information processing apparatus 300 and the system (refer to FIG. 12) in which the connection destination of the display part 150 is the network 600.

Furthermore, the display 150 may include the information processing apparatus 300 within itself.

The information to be displayed on this display part 150 is, for example, what is termed as POP advertising information, such as information on bargain sales of a retail shop in a case where the thermal printer 200 attached to this printer stand 100 is set up in an accounting place of this retail shop.

To put it specifically, the POP advertising is that in which: sheets of paper are used as advertizing media; and names, prices, advertisement slogans, descriptions, illustrations and the like of goods are written or drawn on sheets of paper by hand and the like. However, the printer stand 100 according to this embodiment displays electronic POP advertising information obtained by converting this POP advertising information into electronic information, as visible images (including characters), on the display screen of the display part 150.

Meanwhile, the thermal printer 200 prints the prices and the like of the goods on sheets of paper, and discharges the printed sheets of paper from the sheet discharge port 220. Because the sheets of paper discharged from the sheet discharge port 220 are taken out by a salesclerk who carries out the accounting process, the thermal printer 200, which is placed in the vertical posture while attached to the printer stand 100, is set up with this sheet discharge port 220 faced toward the salesclerk. The display part 150 of the printer stand 100 is faced to a purchaser, or a customer who stands to face this salesclerk.

Moreover, the printer stand 100 can not only hold the thermal printer 200 with its posture changed, but also stimulate the customer's motive, by displaying information, such as the electronic POP advertizing information, on the display part 150.

In addition, because the display part 150 is provided on the surface of the back plate 121, which is opposite from the surface in which the thermal printer 200 is set up, the display surface of the display part 150 is faced toward the customer who is the purchaser standing to face the salesclerk using the thermal printer 200. Accordingly, the display part 150 can exert the advertisement function on the customer effectively.

In the case of the conventional POP advertising using paper media, a paper medium in which the POP advertising information is drawn needs to be folded three-dimensionally for preventing the paper medium from collapsing, or a collapse-preventing support needs to be formed on a surface on the rear of the surface on which the POP advertising information is drawn. For this reason, the conventional POP advertising requires an occupying area in the depth direction to be secured relatively widely. On the contrary, the electronic POP advertising through the display part 150 of this printer stand 100 only increases the occupying area in the depth direction by the thickness of the display part 150 in addition to the thickness of the main body of the printer stand 100. For this reason, the electronic POP advertising can make its occupying area in the setup place smaller than the conventional POP advertising using the paper medium.

It is a matter of course that the electronic POP advertising information to be displayed on this display part 150 can be sequentially or randomly switched from one piece of information to another at intervals of a predetermined time length under the control of the information processing apparatus 300. Accordingly, the electronic POP advertising can offer more pieces of information in a wider variety of display modes than the conventional POP advertising using paper media. In addition, the electronic POP advertising can display information whose display time and the like are limited, such as an announcement of a time-limited sale, in a timely manner as well.

Furthermore, the information to be displayed on the display part 150 is not limited to the electronic POP advertising information. Information on the accounting process concerning the goods, which is serially displayed on the display part of the cash register, may be displayed on the display part 150.

Note that, in a case where a retail shop uses the information processing apparatus 300, the thermal printer 200 and the printer stand 100 provided with the display part 150 as the account processing system substituting the cash register, a cash drawer 400 for keeping cash and a scanner for reading bar codes and the like attached to goods may be added to the information processing apparatus 300, the thermal printer 200 and the printer stand 100, as shown in FIGS. 11 and 12.

Moreover, the display part 150 may include a touch panel 157 (refer to FIG. 8) overlapping the display surface, and may be configured to function as an input interface by use of information displayed on the display surface of the display part 150 and a portion of the touch panel 157 which corresponds to a region in which the information is displayed.

It is conceivable that the retail shop handles not only a cash accounting process but also a credit card transaction. In the case of the credit card transaction, the credit card user is requested to enter his/her personal identification number (PIN).

Hence, an image of a numeric key is displayed (displayed pieces of information), as a software-based keyboard, on the display part 150 of the above-described printer stand 100, and portions of the touch panel 157 which correspond to the images of the number of the numeric key is configured to function as an input interface. Thereby, a customer is prompted to enter his/her personal identification number through the touch panel of the display part 150. This can achieve an input interface without separately providing a numeric key input device as a piece of hardware, and can also process the credit card transaction.

In addition, suppose a case where a customer is rewarded with predetermined benefits and the like at a time of an accounting process on the basis of his/her accumulation of a predetermined number of shopping reward points or his/her purchase of a specific piece of merchandise. In this case, if the touch panel is provided in the display part 150, the customer can do things such as inputting an operation for choosing a benefit through the display part 150. This can make the printer stand 100 more useful.

Note that, because the display part 150 is detachable from the back plate 121 of the printer stand 100, the printer stand 100 can be used with the display part 150 being detached therefrom while the display part 150 is under maintenance or the like.

In addition, while the display part 150 is being detached therefrom (while the display part 150 and the main body 130 are being separated from each other), the above-described claws 126, 127 can also hold the conventional paper medium (plate-shaped medium) carrying POP adverting information thereon, in the spaces between the claws 126, 127 and the back plate 121 unassistedly (with no supports provided on the rear surface of the paper medium). For this reason, the use value of the printer stand 100 can be enhanced, too, while the display part 150 is being separated therefrom, such as while the display part 150 is under maintenance.

The printer stand 100 according to this embodiment has been described on the assumption that the printer stand 100 is for the thermal printer 200 used as a part of the account processing system substituting the cash register in an accounting place in a retail shop. Nevertheless, the thermal printer 200 used in this embodiment is used not only for the use mode in such a business, but also for other use modes such as issuing number tickets for customers waiting for services to be offered in hospitals and financial institutions, issuing search results for showing the locations and the like of searched books in bookstores and libraries, and printing the values representing measurements made by general measuring equipment.

Furthermore, the display part 150 of the printer stand 100 to which the thermal printer 200 is attached can be designed to display appropriate pieces of information depending on a place (a retail shop, hospital, financial institution, bookstore, library or the like) where the thermal printer 200 is used.

For this reason, the printer stand 100 according to this embodiment can not only hold the thermal printer 200 with the posture of the thermal printer 200 changed, but also cause the display part 150 to display useful pieces of information which are appropriate depending on the place where the thermal printer 200 is used. Accordingly, the use value as the printer stand 100 can be enhanced.

A printer stand according to the embodiment of present invention enhances its value by: including a main body for supporting a printer with its setup posture being changed, and a display part; and displaying various pieces of information, such as electronic POP advertisements, on the display part.

In other words, the printer stand according to the embodiment of the present invention is characterized by including: a main body into which a base part and a support part are integrally formed; and a display part on which to display information. The base part is in contact with a surface (a top surface of a cashier's counter and the like) on which the printer stand is set up. The support part is that to which the printer is detachably attached with the printer's setup posture changed.

The thus-configured printer stand according to the embodiment of the present invention functions as a printer stand for supporting the printer with its setup posture changed, with the printer being attached to the support part of the main body by changing its setup posture (with the printer being attached to the support part thereof in a setup posture different from the setup posture in which the printer is set up when used alone), and with the base part of the main body being in contact with the setup surface. In addition, the printer stand can be used as an advertisement medium by causing the display part, which is provided on this printer stand, to display various information. Accordingly, the printer stand can enhance its use value.

The printer stand according to the embodiment of the present invention can enhance its use value.

Although the embodiments of the present invention have been described above, the present invention is not limited thereto. It should be appreciated that variations may be made in the embodiments described by persons skilled in the art without departing from the scope of the present invention.

What is claimed is:

1. A printer stand comprising:
a main body into which a base part and a support part are integrally formed, the base part being in contact with a surface on which the printer stand is set up, the support part being that to which a printer is detachably attached with its setup posture changed; and
a display part for displaying information.

2. The printer stand according to claim 1, wherein
the display part is provided on a surface opposite from a surface to which the printer is attached in the main body.

3. The printer stand according to claim 1, wherein
the display part and the main body include engagement parts which are engageable with and disengageable from each other in a way that: when the engagement parts are engaged with each other, the display part and the main body are integrated together; and when the engagement parts are disengaged from each other, the display part and the main body are separated from each other.

4. The printer stand according to claim 2, wherein
the display part and the main body include engagement parts which are engageable with and disengageable from each other in a way that: when the engagement parts are engaged with each other, the display part and the main body are integrated together; and when the engagement parts are disengaged from each other, the display part and the main body are separated from each other.

5. The printer stand according to claim 3, wherein
the engagement part included in the main body is formed from a plurality of claws capable of holding a plate-shaped medium in a state where the display part is separated from the main body.

6. The printer stand according to claim 4, wherein
the engagement part included in the main body is formed from a plurality of claws capable of holding a plate-shaped medium in a state where the display part is separated from the main body.

7. The printer stand according to claim 1, wherein
the display part includes at least one of: an input part to be connected to an external information processing apparatus for outputting information intended to be displayed on the display part; and a medium connecting part to which a storage medium is connected, the storage medium having the information intended to be displayed on the display part stored therein.

8. The printer stand according to claim 2, wherein
the display part includes at least one of: an input part to be connected to an external information processing apparatus for outputting information intended to be displayed on the display part; and a medium connecting part to which a storage medium is connected, the storage medium having the information intended to be displayed on the display part stored therein.

9. The printer stand according to claim 1, wherein
the display part includes a touch panel, and functions as an input interface by use of: the information displayed on the display part; and a portion of the touch panel, the portion corresponding to a region in which the information is displayed.

10. The printer stand according to claim 2, wherein
the display part includes a touch panel, and functions as an input interface by use of: the information displayed on the display part; and a portion of the touch panel, the portion corresponding to a region in which the information is displayed.
